(19) United States
(12) Patent Application Publication
(10) Pub. No.: US 2006/0081970 A1
(43) Pub. Date: Apr. 20, 2006

(54) Memory card module with an inlay design

(76) Inventor: Yuang Chih Wu, Hsin Chu (TW)

Correspondence Address: PRO-TECHTOR INTERNATIONAL, 20775 Norada Court, Saratoga, CA, 95070-3018, US

(21) Appl. No.: 10/969,385

(22) Filed: Oct. 19, 2004

(51) Int. Cl. H01L 23/495

(52) U.S. Cl. 257/679

(57) ABSTRACT

A memory card module with an inlay design includes a substrate having an upper surface on which an upper cavity is formed, and a lower surface on which at least a lower cavity corresponding to the upper cavity of the upper surface is formed, a through hole is penetrated from the upper cavity to the lower cavity. A memory chip on which a plurality of pads are formed, and is arranged within the upper cavity of the substrate, wherein the pads formed on the memory chip are located at the through hole. A plurality of wires are electrically connected the pads formed on the memory chip to the lower cavity through the hole. A first compound resin is filled within the upper cavity for encapsulating the memory chip. A second compound resin is filled within the lower cavity for encapsulating the wires.

### BACKGROUND OF THE INVENTION

1. Field of the invention

The invention relates to a memory card module, and in particular to a memory card module with an inlay design, it may manufacture easily, and can decrease the damage to increase the production yield.

2. Description of the Related Art

Referring to FIG. 1, is a cross-section view of a conventional memory chip package, the memory chip package 11 comprises a substrate 10, a memory chip 12, a plurality of wires 14, and a compound resin 16. The memory chip 12 is mounted on the substrate 10, and electrically connected to the substrate 10 by wires 14. Hereinafter, the compound resin 16 is encapsulated on the memory chip 12 and wires 14 to be a memory chip package 11.

Please referring to FIG. 2, is a cross-section view of a conventional memory card module comprises a printed circuit board 18 and a plurality of memory chip package 11. The each of memory chip package 11 are arranged on the printed circuit board, and electrically connected to the printed circuit board 18 by ball grid array 20.

However in memory card module of the aforesaid construction has following drawbacks.
1. Since each of the memory chips are packaged individual, hereinafter, the each of the memory chip packages are mounted on the printed circuit board, and electrically connected to the printed circuit board by ball grid array, therefore, the process of manufacturing is complicated, and can not decrease the cost of the manufacturing.
2. Since each of the memory chip packages are mounted on the printed circuit board, and electrically connected to the printed circuit board by ball grid array, therefore, the volume of the memory card module is can not decrease.

### SUMMARY OF THE INVENTION

An objective of the invention is to provide a memory card module with an inlay design, which may be decreased the volume of the module

Further objective of the invention is to provide a memory card module with an inlay design, which may manufacture easily, and can decrease the damage to increase the production yield.

To achieve the above-mentioned object, the invention includes a substrate, at least a memory chip, a plurality of wires, a first compound resin, and a second compound resin. The substrate has an upper surface on which at least an upper cavity is formed, and a lower surface on which at least a lower cavity corresponding to each of the upper cavity of the upper surface is formed, a through hole is penetrated from the upper cavity to the lower cavity, the diameter of the through hole is smaller than the upper cavity and the lower cavity. The at least a memory chip on which a plurality of pads are formed is arranged within the upper cavity of the substrate, wherein the pads formed on the memory chip are located at the through hole. The plurality of wires are electrically connected the pads formed on the memory chip to the lower cavity through the hole. The first compound resin is filled within the upper cavity for encapsulating the memory chip. The second compound resin is filled within the lower cavity for encapsulating the wires.

### BRIEF DESCRIPTION OF THE DRAWINGS

FIG. 1 is a schematic illustration view showing a conventional memory chip package.

FIG. 2 is cross-section view showing a conventional memory card module.

FIG. 3 is a cross-section view showing a memory card module with an inlay design of the present invention.

FIG. 4 is a cross-section view showing a substrate of memory card module with an inlay design of the present invention.

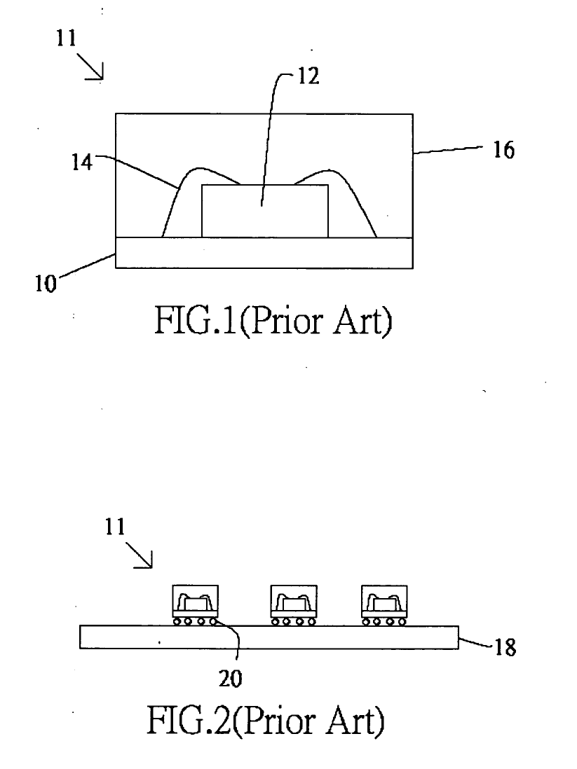

### DETAILED DESCRIPTION OF THE INVENTION

The preferred embodiments are described hereinafter with reference to the accompanying drawings.

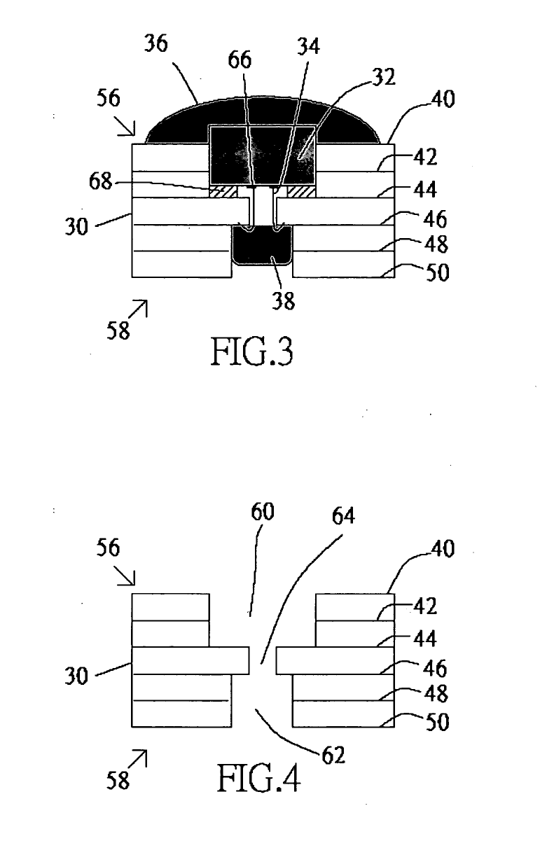

Please refer to FIG. 3 is a memory card module of the present invention includes a substrate30, a memory chip 32, a plurality of wires 34, a first compound resin 36, and a second compound resin 38.

Please refer to FIG. 4 is the substrate of a memory card module with an inlay design of the present invention. As shown in FIG. 4, the substrate 30 includes six layer boards 40, 42, 44, 46, 48, and 50. The substrate 30 has an upper surface 56 on which an upper cavity 60 is formed, and a lower surface 58 on which a lower cavity 62 corresponding to the upper cavity 60 of the upper surface 56 is formed, a through hole 64 is penetrated from the upper cavity 60 to the lower cavity 62, the diameter of the through hole 64 is smaller than the upper cavity 60 and the lower cavity 62. In the embodiment, the upper cavity 60is formed between the first layer board 40 and second layer board 42, the lower cavity 62 is formed between the five layer board 48 and six layer board 50, the through hole is formed between the third layer board 44 and four layer board 46.

The memory chip 32 on which the plurality of pads 66 are formed, and is adhered within the upper cavity 60 of the substrate 30 by heat conductive glue 68, wherein the pads 66 formed on the memory chip 32 are located at the through hole 64. The memory chip 32

The plurality of wires 34 are electrically connected the pads 66 formed on the memory chip 32 to the lower cavity 62 through the through hole64.

The first compound resin 36 is filled within the upper cavity 60 for encapsulating the memory chip32.

The second compound resin 38 is filled within the lower cavity 62 for encapsulating the wires34.

Therefore, the memory card module with an inlay design of the present invention has following advantage.
1. Since the memory chip 32 is inlayed within the upper cavity 60 of the substrate 30, and the wires 34 is inlayed within the lower cavity 62, so that the volume of the module may be decreased.
2. Since the memory chip 32 is adhered within the upper cavity 60 of the substrate 30 by heat conductive glue 68, so that the head from the memory chip 30 may be radiated quickly.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. A memory card module with an inlay design comprising:
a substrate having an upper surface on which at least an upper cavity is formed, and a lower surface on which at least a lower cavity corresponding to each of the upper cavity of the upper surface is formed, a through hole is penetrated from the upper cavity to the lower cavity, the diameter of the through hole is smaller than the upper cavity and the lower cavity;
at least a memory chip on which a plurality of pads are formed, said memory chip is arranged within the upper cavity of the substrate, wherein the pads formed on the memory chip are located at the through hole;
a plurality of wires electrically connected the pads formed on the memory chip to the lower cavity through the through hole;
a first compound resin filled within the upper cavity for encapsulating the memory chip; and
a second compound resin filled within the lower cavity for encapsulating the wires.

2. The memory card module with an inlay design according to claim 1, wherein the memory chip is adhered to the upper cavity by heat conductive glue.

3. The memory card module with an inlay design according to claim 1,
wherein the substrate comprises six layer boards, the upper cavity is formed between the first layer board and second layer board, the lower cavity is formed between the five layer board and six layer board, the through hole is formed between the third layer board and four layer board.
